(19) United States
(12) Patent Application Publication
(10) Pub. No.: US 2026/0107714 A1
(43) Pub. Date: Apr. 16, 2026

(54) Selective Etching of Silicon Dioxide and Silicon Nitride Containing Materials

(71) Applicant: The Regents of the University of Colorado, a Body Corporate, Denver, CO (US)

(72) Inventors: Steven George, Boulder, CO (US); Marcel Junige, Boulder, CO (US)

(21) Appl. No.: 19/355,233

(22) Filed: Oct. 10, 2025

Related U.S. Application Data
(60) Provisional application No. 63/706,979, filed on Oct. 14, 2024.

(51) Int. Cl. H01L 21/311; C09K 13/08

(52) U.S. Cl. CPC H10P 50/283; C09K 13/08

(57) ABSTRACT

Provided herein are methods for selectively etching substrates containing silicon dioxide and silicon nitride. The methods enable selective etching of silicon dioxide or silicon nitride in the presence of both materials.

### CROSS-REFERENCE TO RELATED APPLICATION

The present application claims priority under 35 U.S.C. § 119(e) to U.S. Provisional Patent Application 63/706,979, filed Oct. 14, 2024, the contents of which are hereby incorporated by reference in their entirety.

### BACKGROUND

Microelectronics processing methods are being challenged by sub-10-nm technology node requirements to fabricate advanced, three-dimensional (3D) device structures. Overcoming the limits of top-down patterning requires breakthroughs in nanomanufacturing techniques. Bottom-up, self-aligned approaches provide a crucial solution by eliminating lithographic photomasks and associated edge-placement errors. Self-alignment methods include area-selective deposition or etching for a range of materials.

Etch selectivity may remove one specific material while leaving intact other materials in proximity. The development of selectivity between similar materials, such as silicon (Si)-based dielectrics, is a particular challenge. There is a pressing need for selectively etching of silicon dioxide (SiO₂) with retention of silicon nitride (SiNₓ), and the reciprocal challenge of selective SiNₓ etching while retaining SiO₂.

The present disclosure addresses this unmet need.

### SUMMARY OF THE INVENTION

In various aspects, a method of etching a substrate is provided. The method includes: contacting, in a reaction chamber, the substrate with an etching reagent comprising hydrogen fluoride (HF) and optionally a polar molecule having a dipole moment of at least 1 Debye; and etching the substrate, wherein the substrate comprises silicon dioxide (SiO₂) and silicon nitride (SiNₓ).

Advantageously, in various aspects, the etching can be spontaneous etching, which includes etching that continuously removes the targeted material without any self-limiting reaction steps that stop the etching process.

### BRIEF DESCRIPTION OF THE FIGURES

The drawings illustrate generally, by way of example, but not by way of limitation, various embodiments of the present application.

FIG. 1 is a schematic for SiO₂ thermal ALE (atomic layer etching) based on sequential TMA and HF exposures that perform the reactions: ligand-exchange by TMA (trimethyl aluminum); conversion by TMA; and fluorination by HF, in accordance with various embodiments.

FIG. 2 shows SiO₂ layer thickness versus ALE cycle number for SiO₂ thermal ALE at 275° C. Each data point represents a single static reactant exposure for TMA or HF of 3 Torr for 45 s, in accordance with various embodiments. SiO₂ thickness decreased linearly versus ALE cycles with an EPC of 0.20 Å/cycle.

FIG. 3 shows SiO₂ layer thickness versus exposure number of only TMA or HF exposures by themselves, in accordance with various embodiments. Each individual reactant exposure of TMA or HF was 3 Torr for 45 s. Spontaneous etching of SiO₂ occurred at a rate of 0.02 Å per 45 s HF exposure.

FIG. 4 shows SiNₓ layer thickness versus ALE cycle number for SiNₓ thermal ALE at 275° C., in accordance with various embodiments. Each data point represents a single static reactant exposure for TMA or HF of 3 Torr for 45 s. SiNₓ thickness decreased linearly versus ALE cycles with an EPC of 1.06 Å/cycle.

FIG. 5 shows SiNₓ layer thickness versus exposure number of only TMA or HF exposures by themselves, in accordance with various embodiments. Each individual reactant exposure of TMA or HF was 3 Torr for 45 s. Spontaneous etching of SiNₓ occurred at a rate of 1.29 Å per 45 s HF exposure.

FIG. 6 shows film thickness versus ALE cycle number for SiO₂, SiNₓ, and Al₂O₃ thermal ALE using TMA and HF exposures at 275° C. EPCs were 2.61, 1.06, and 0.20 Å/cycle for Al₂O₃, SiNₓ, and SiO₂, respectively, in accordance with various embodiments. Selectivity factor was ˜5:1 for SiNₓ etching compared to SiO₂ etching (preferential SiNₓ removal).

FIG. 7 shows film thickness versus HF exposure number comparing SiO₂ and SiNₓ spontaneous etching using HF alone at 275° C., in accordance with various embodiments. Etch rates were 1.72 Å/min for SiNₓ and 0.03 Å/min for SiO₂. Selectivity factor was ˜50:1 for SiNₓ etching compared to SiO₂ etching (preferential SiNₓ removal) at 3 Torr HF pressure.

FIGS. 8A-8B shows FIG. 8A) SiO₂ layer thickness versus ALE cycle number for SiO₂ thermal ALE using TMA and HF+NH₃ co-dosing at 275° C., in accordance with various embodiments. Each data point represents a single static reactant exposure for TMA or HF+NH₃ of 3 Torr for 45 s. SiO₂ thickness decreased versus ALE cycles with an EPC of 8.83 Å/cycle averaged over 15 ALE cycles. FIG. 8B) SiO₂ layer thickness versus HF+NH₃ exposure number. Each HF+NH₃ exposure was 3 Torr for 45 s. Spontaneous etching of SiO₂ occurred at a rate of 20.62 Å per 45 s HF+NH₃ exposure.

FIGS. 9A-9B shows FIG. 9A) SiNₓ layer thickness versus ALE cycle number for SiNₓ thermal ALE using TMA and HF+NH₃ co-dosing at 275° C., in accordance with various embodiments. Each data point represents a single static reactant exposure for TMA or HF+NH₃ of 3 Torr for 45 s. SiNₓ thickness remained virtually constant versus ALE cycles. FIG. 9B) SiNₓ layer thickness versus HF+NH₃ exposure number. Each HF+NH₃ exposure was 3 Torr for 45 s. Spontaneous etching of SiNₓ occurred at a rate of 0.01 Å per 45 s HF+NH₃ exposure.

FIG. 10 shows a comparison between SiO₂ and SiNₓ film thickness versus ALE cycle number for thermal ALE using TMA and HF+NH₃ co-dosing at 275° C., in accordance with various embodiments. EPCs were 8.83 Å/cycle for SiO₂ and <0.01 Å/cycle for SiNₓ. Selectivity factor was >1000:1 for SiO₂ etching compared to SiNₓ etching (preferential SiO₂ removal).

FIG. 11 shows a comparison between SiO₂ and SiNₓ film thickness versus HF+NH₃ exposure number for spontaneous etching at 275° C., in accordance with various embodiments. Etch rates were 27.50 Å/min for SiO₂ and 0.02 Å/min for SiNₓ. Selectivity factor was >1000:1 for SiO₂ etching compared to SiNₓ etching (preferential SiO₂ removal).

FIGS. 12A-12D show spontaneous etching scenarios for SiO₂ and SiNₓ using HF exposures or HF+NH₃ co-dosing exposures, in accordance with various embodiments. FIG. 12A) No etching of SiO₂ for HF exposures and near-ideal ALE synergy. FIG. 12B) Major spontaneous etching of SiNₓ for HF exposures and no ALE synergy. FIG. 12C) Rapid spontaneous etching of SiO₂ for HF+NH₃ or DMA+HF co-dosing exposures and no ALE synergy. FIG. 12D) No etching of SiNₓ for HF+NH₃ exposures.

FIG. 13 shows the differences between atomic layer etching (ALE) and spontaneous etching, according to various embodiments. Both methods are examples of thermal dry etching.

FIG. 14 provides proposed chemical equilibria of etch species depending on whether a polar molecule is present or absent with the HF, according to various embodiments.

FIG. 15 shows a process of SiO₂ “Non-Etch” using anhydrous HF vapor vs. SiO₂ spontaneous etching using co-dosing of dimethylamine (DMA)+HF, in accordance with various embodiments.

FIG. 16 shows negligible SiO₂ thickness loss during consecutive DMA exposures (below ±0.01 Å/exposure), implying negligible SiO₂ spontaneous etching by DMA alone, in accordance with various embodiments. Protocol: 45 s evacuate—DMA (20° C.) dose to 3 Torr, 45 s static exposure—30 s evacuate—120 s 150 sccm Ar purge; 200° C.

FIG. 17 shows etch rate versus HF pressure comparing SiO₂ and SiNₓ spontaneous etching using HF alone at 275° C., in accordance with various embodiments. Selectivity factor was ˜150:1 for SiNₓ etching compared to SiO₂ etching (preferential SiNₓ removal) at 9 Torr HF pressure.

FIG. 18 shows de-facto SiO₂ non-etch using 3 and 9 Torr anhydrous HF vapor, respectively, at 275° C., after coating the reactor walls and sample holder with ZrF₄ to obtain better H₂O-free conditions during fluorination, in accordance with various embodiments.

FIG. 19 describes characteristics of polar co-adsorbates for use with anhydrous HF vapor, in accordance with various embodiments.

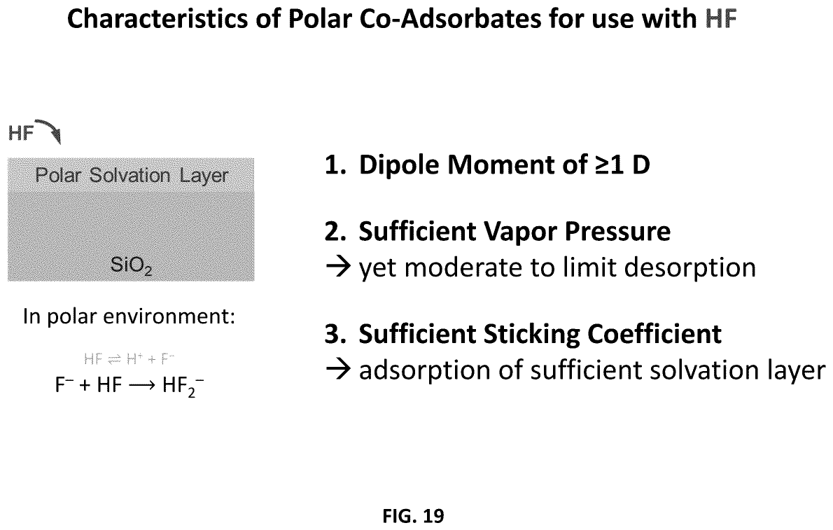

### DETAILED DESCRIPTION OF THE INVENTION

Reference will now be made in detail to certain embodiments of the disclosed subject matter. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

### Definitions

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that the composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less. The term “substantially free of” can mean having a trivial amount of, such that a composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

The term “alkyl” as used herein refers to straight chain and branched alkyl groups and cycloalkyl groups having from 1 to 40 carbon atoms, 1 to about 20 carbon atoms, 1 to 12 carbons or, in some embodiments, from 1 to 8 carbon atoms. Examples of straight chain alkyl groups include those with from 1 to 8 carbon atoms such as methyl, ethyl, n-propyl, n-butyl, n-pentyl, n-hexyl, n-heptyl, and n-octyl groups. Examples of branched alkyl groups include, but are not limited to, isopropyl, iso-butyl, sec-butyl, t-butyl, neopentyl, isopentyl, and 2,2-dimethylpropyl groups. As used herein, the term “alkyl” encompasses n-alkyl, isoalkyl, and anteisoalkyl groups as well as other branched chain forms of alkyl. Representative substituted alkyl groups can be substituted one or more times with any of the groups listed herein, for example, amino, hydroxy, cyano, carboxy, nitro, thio, alkoxy, and halogen groups.

The term “solvent” as used herein refers to a liquid that can dissolve a solid, liquid, or gas. Non-limiting examples of solvents are silicones, organic compounds, water, alcohols, ionic liquids, and supercritical fluids.

The term “independently selected from” as used herein refers to referenced groups being the same, different, or a mixture thereof, unless the context clearly indicates otherwise. Thus, under this definition, the phrase “X¹, X², and X³ are independently selected from noble gases” would include the scenario where, for example, X¹, X², and X³ are all the same, where X¹, X², and X³ are all different, where X¹ and X² are the same but X³ is different, and other analogous permutations.

The term “room temperature” as used herein refers to a temperature of about 15° C. to 28° C.

The term “standard temperature and pressure” as used herein refers to 20° C. and 101 kPa.

### Methods of Selective Etching

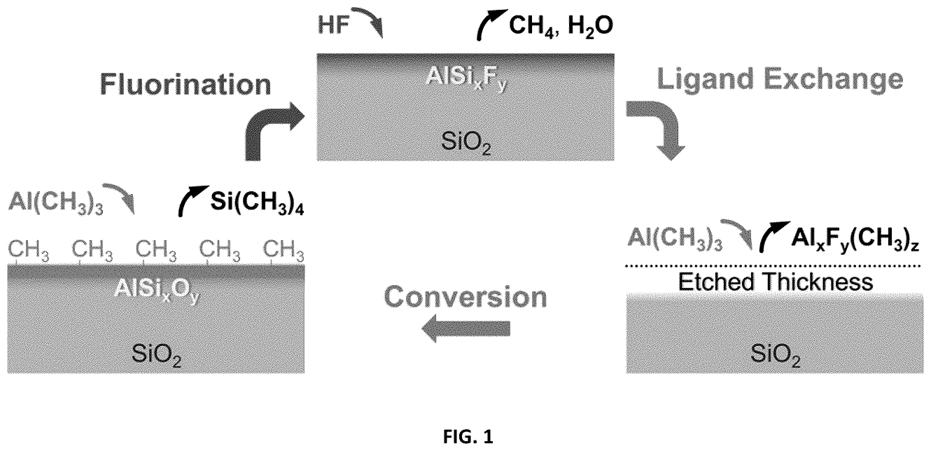

Atomic layer control of dry thermal etching can be obtained using atomic layer etching methods (ALE). ALE employs an alternating sequence of separate, self-limiting surface reactions. The first reaction typically modifies the surface and the second reaction volatilizes the modified surface layer. Thermal ALE processes have been developed for a variety of Si-containing materials such as Si, SiO₂, Si₃N₄, and silicon-germanium (SiGe). FIG. 1 illustrates the surface chemistry for SiO₂ thermal ALE. This chemistry combines ligand-exchange and conversion reactions by trimethylaluminum (TMA, Al(CH₃)₃) together with fluorination by hydrogen fluoride (HF).

The TMA reaction removes an AlF₃ surface layer by ligand exchange, producing volatile Al₂Fₓ(CH₃)_{y} dimers and Al₃Fₓ(CH₃)_{y} trimers. At sufficient TMA exposures, TMA also converts the SiO₂ surface into a mixture of Al₂O₃, aluminosilicate, and reduced Si species. Methyl groups terminate the converted AlSiₓO_{y} surface layer. The conversion reaction produces tetramethylsilane (Si(CH₃)₄) as volatile product. SiO₂ surfaces need this conversion because SiO₂ by itself has no direct etch pathway by fluorination and ligand-exchange reactions at lower TMA exposures in the absence of conversion. HF then fluorinates the Al₂O₃ surface, forming an AlF₃ surface layer. The fluorination reaction produces methane (CH₄) and water (H₂O) as volatile products.

The benefits for thermal ALE depend on the self-limiting characteristics of each reaction step. A problem can occur when spontaneous etch pathways continuously remove the targeted material. A synergy factor has been introduced to quantify the ideality of an ALE sequence that alternates between separate A and B reactions compared with repeating one reaction step individually:³¹

$$ALE Synergy = \frac{E P C - ( α + β )}{E P C} \cdot 100 \% \qquad ( 1 )$$

The etch per cycle (EPC) is the thickness loss derived from the A/B reaction sequence. The spontaneous etch rates α or β can contribute to etching during the individual A or B reactions, respectively. α and β can be measured as thickness loss during separate processing with multiple consecutive exposures of one of the reactants alone. The ALE synergy approaches an ideal of 100% when all etching is derived solely from a favorable interaction of the sequential A and B reactions and no etching occurs from either reaction by itself.

This study determined selectivity by performing thermal ALE and spontaneous etching experiments on SiO₂ and SiNₓ under identical reaction conditions. A selectivity factor has been defined to quantify how much a particular process removes the “etch” versus “non-etch” material:³¹

$$Selectivity ( S ) = \frac{E P C ( e t c h )}{{EPC}^{′} ( non - etch )} or \frac{{β}_{H F} ( e t c h )}{{β}_{H F} ( non - etch )} \qquad ( 2 )$$

EPC(etch) and β_{HF}(etch) denote the thickness loss for the “etch” material. Conversely, EPC′(non-etch) and β′_{HF}(non-etch) denote the thickness loss for the “non-etch” material. The selectivity factor approaches an ideal of ∞ when an etch process removes the “etch” material exclusively and retains all “non-etch” material.

A previous study has achieved selectivity with >10 times faster etching for SiGe thermal ALE compared to Si(100) or Si₃N₄ thermal ALE. This selectivity has been attributed to larger rates for SiGe oxidation and conversion under the same reaction conditions at 290° C. The present work attempted to develop selectivity between SiO₂ and SiNₓ based on differences between the ligand-exchange, conversion, and fluorination reactions during thermal ALE. Other studies have achieved selectivity between SiO₂ and SiNₓ using wet or plasma etching approaches.

In various embodiments, provided herein are methods of selectively etching between SiO₂ and SiNₓ for thermal ALE using TMA and HF as the reactants. In various embodiments, provided herein are methods of spontaneous etching of SiO₂ versus SiNₓ using HF alone. In various embodiments, provided herein are methods for selectively etching between SiO₂ and SiNₓ for a modification of the thermal ALE process using TMA and a co-dose of HF with a polar molecule such as ammonia (NH₃). In various embodiments, provided herein are methods of spontaneous etching of SiO₂ versus SiNₓ by co-dosing HF with a polar molecule such as NH₃.

### Substrates

In various embodiments, the etching methods describe herein etch substrates, surfaces of a substrate, or portions of a surface of a substrate. The substrate can be a cleaned substrate (i.e., a substrate from which impurities are at least partially removed) obtained, for example, according to the methods described herein. The substrate can be a porous substrate or a high-aspect-ratio structure obtained according to the methods described herein. Substrates can also include 3D structures with reduced feature sizes obtained, for example, according to the methods of the invention. The substrate can also be a patterned substrate or a smoothened substrate obtained, for example, according to the methods described herein. Substrates with the described morphologies and/or characteristics produced by art recognized methods can also be used.

In certain embodiments, the substrate comprises at least one material such as Si, SiNₓ, SiO₂, SiNₓO_{y}, SiₓGe_{y}, SiC, SiB₃, SiP, SiAs, SiSe, or SiTe, and the like, or mixtures thereof, where x is an integer from 1 to 6 and y is an integer from 1 to 6. In various embodiments, the substrate contains both SiO₂ and SiNₓ, which can be in at least one individual layer of each respective substance, or a mixture of the two in a single layer. When present in individual layers, the number of layers of each of SiO₂ and SiNₓ need not be numerically equivalent, and the number of layers of each substance can be any suitable number as dictated by the needs of the particular device, structure or application. For example, in various embodiments, the substrate can include 1 to 100, 1 to 500, 1 to 1000, or 1 to 10,000 layers of each of SiO₂ and SiNₓ. In various embodiments, the layers of SiO₂ and SiNₓ are alternating layers.

In other embodiments, the substrate comprises at least one material such as RuSi, TiₓSi_{y}, TiC_{z}, VₓSi_{y}, NbₓSi_{y}, MoₓSi_{y}, TaₓSi_{y}, ReₓSi_{y}, or WₓSi_{y}, or mixtures thereof, and the like, where x is an integer from 1 to 6, y is an integer from 1 to 6, and z is from about 0.3 to about 1. In various embodiments, z is about 0.50, 0.625, 0.75, 0.85, 0.90, or about 1.0. In various embodiments, z is 1.

In certain embodiments, prior to etching as described herein, the substrate is first treated such that at least a portion of the surface of the substrate becomes coated (including conformally coated) a metal compound selected from the group consisting of a metal oxide, metal nitride, metal phosphide, metal sulfide, metal arsenide, metal fluoride, metal silicide, metal boride, metal carbide, metal selenide, metal telluride, elemental metal, metal alloy, and hybrid organic-inorganic material. The metal can be any metal that is suitable for or compatible with the methods described herein, and can be Al, Hf, Zr, Fe, Ni, Co, Mn, Mg, Rh, Ru, Cr, Si, Ti, Sc, Ga, In, Zn, Pb, Ge, Ta, Cu, W, Mo, Pt, Nb, Cd or Sn, and combinations of any of the preceding metals and/or metal compounds. When the compound is an elemental metal, the elemental metal can be converted to a metal oxide by adding an oxidation step to the etching process, for example prior to exposing the elemental metal to HF. This type of oxidation can be accomplished by, for example, using thermal O₂ or 03 oxidation. Likewise, this oxidation can be accomplished with an O₂ plasma.

### Non-limiting Etching Methods

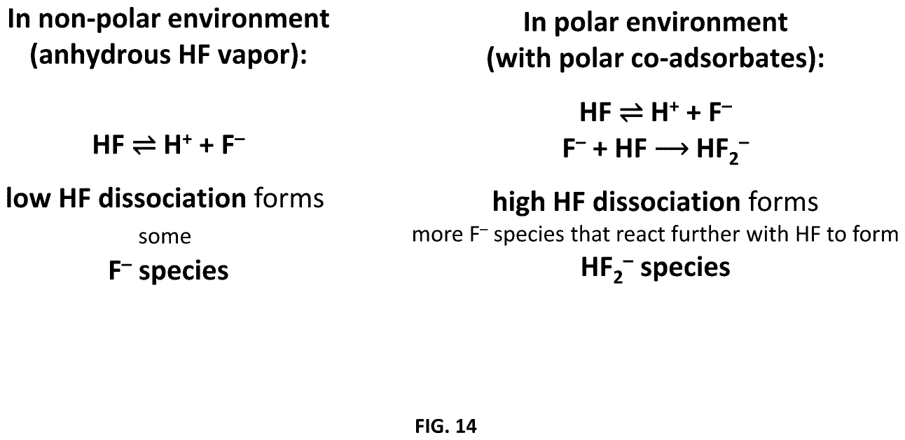

In various embodiments, a method of etching a substrate is provided. The method includes contacting, in a reaction chamber, the substrate with an etching reagent that includes hydrogen fluoride (HF) and optionally a polar molecule having a dipole moment of at least 1 Debye; and etching the substrate. The substrate, in various embodiments contains silicon dioxide (SiO₂) and silicon nitride (SiNₓ). The presence or absence of the polar molecule in the reaction chamber determines the nature of the etching species and therefore whether silicon dioxide or silicon nitride is etched. As shown in FIG. 14, in the absence of the polar molecule, F⁻ is the primary etching species and allows for selective etching of silicon nitride in the presence of silicon dioxide. In the presence of a polar molecule, which, in various embodiments acts as a co-adsorbate, HF₂⁻ is the primary etching species and allows for selective etching of silicon dioxide in the presence of silicon nitride. In various embodiments, the method allows for a switching protocol where the polar molecule is added or removed (such as by vacuum pump) from the reaction chamber as many times as desired, thereby allowing for selective etching of the desired substrate. Thus, provided herein, in various embodiments, is a gas-phase (dry), non-plasma-based (thermal) method to selectively etch SiO₂ but retain SiNₓ, or selectively etch SiNₓ but retain SiO₂.

The present methods have significant advantages over other types of etching techniques, such as liquid etching or plasma etching. For example, liquid-phase (wet) etching (in solution) suffers from capillary action in miniaturized, high-aspect-ratio pattern features, leading to pattern collapse. Plasma etching is a directional/anisotropic form of etching, which also requires line of sight and harsh conditions. In contrast, the thermal methods described herein allow for isotropic and/or lateral material removal with or without line of sight.

The present methods, in various embodiments, also advantageously include a single processing step, which has at least the following benefits:
i) exposures of only one etchant results in a continuous etch reaction (no sequential exposures, separated by purge steps as required in thermal ALE);
ii) elevated temperatures keep spontaneous reaction going with no salt formation (no cyclic reactant exposure then heating);
iii) inherent selectivity (no prior area-deactivation by blocking layers is necessary).

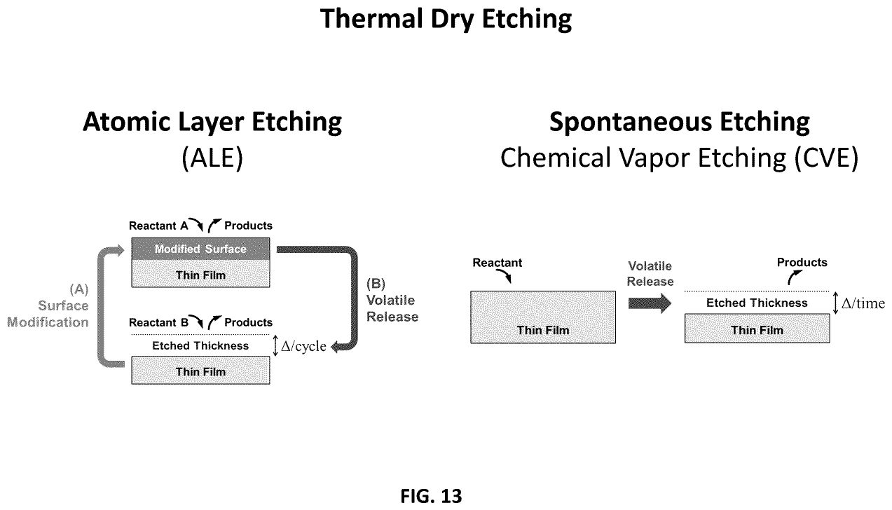

In various embodiments, the etching is spontaneous etching. As used herein, the term “spontaneous etching” means etching that continuously removes the targeted material without any self-limiting reaction steps that stop the etching process. In various embodiments, the etching methods described herein are not atomic layer etching (ALE) methods. In various embodiments, the etching methods described herein do not employ, exhibit, or result in an alternating sequence of separate self-limiting surface reactions. For example, in some embodiments, the methods described herein do not include a first reaction that modifies the surface of a substrate and a second reaction that volatilizes the modified surface layer. FIG. 13 highlights some of the differences between ALE and spontaneous etching, according to various embodiments.

In various embodiments, the substrate further comprises at least one material selected from the group consisting of Si, SiNₓO_{y}, SiₓGe_{y}, SiC, SiB₃, SiP, SiAs, SiSe, SiTe, RuSi, TiₓSi_{y}, TiC_{z}, TiC, VₓSi_{y}, NbₓSi_{y}, MoₓSi_{y}, TaₓSi_{y}, ReₓSi_{y}, and WₓSi_{y}, wherein:
each occurrence of x is independently an integer from 1 to 6;
each occurrence of y is independently an integer from 1 to 6; and
z is from about 0.3 to about 1.

In various embodiments, the substrate further comprises at least one metal compound layer in which the metal is selected from the group consisting of Al, Hf, Zr, Fe, Ni, Co, Mn, Mg, Rh, Ru, Cr, Si, Ti, Sc, Ga, In, Zn, Pb, Ge, Ta, Cu, W, Mo, Pt, Nb, Cd and Sn, and combinations thereof. In various embodiments, metal compound is selected from the group consisting of a metal oxide, metal nitride, metal phosphide, metal sulfide, metal arsenide, metal fluoride, metal silicide, metal boride, metal carbide, metal selenide, metal telluride, elemental metal, metal alloy, and hybrid organic-inorganic material. In various embodiments, the metal compound is a metal oxide. In various embodiments, the metal compound layer is Al.

In various embodiments, the at least one metal compound layer is at least, equal to, or greater than about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or about 100 Å thick. The thickness of each metal compound layer, if there are more than one, can vary independently.

The reaction chamber can be under a vacuum, whereby a vacuum pump operably attached to the reaction chamber continuously maintains a certain vacuum level in the reaction chamber. The reaction chamber can also be under static pressure. Under static pressure the chamber is not actively pumped on and there is no purge gas (Ar, N₂, etc.). The pressure in the chamber during static processing could be anywhere from vacuum to the vapor pressure of the precursors and products.

In various embodiments, the methods described herein are performed at a temperature of about 150 to about 350° C. In various embodiments, the methods described herein are performed at a temperature of equal to or greater than about 150, 155, 160, 165, 170, 175, 180, 185, 190, 195, 200, 205, 210, 215, 220, 225, 230, 235, 240, 245, 250, 255, 260, 265, 270, 275, 280, 285, 290, 295, 300, 305, 310, 315, 320, 325, 330, 335, 340, 345, or about 350° C. In various embodiments, the temperature at which the etching methods described herein are performed is constant, or does not vary by more than 1, 2, 3, 4, or 5° C. during the etching operation. In various embodiments, the methods described herein are performed at a temperature of equal to or greater than about 200° C. In various embodiments, the methods described herein are performed at a temperature of equal to or greater than about 205° C. In various embodiments, the methods described herein are performed at a temperature of equal to or greater than about 210° C. In various embodiments, the methods described herein are performed at a temperature of equal to or greater than about 210° C. In various embodiments, the methods described herein are performed at a temperature of equal to or greater than about 215° C. In various embodiments, the methods described herein are performed at a temperature of equal to or greater than about 220° C. In various embodiments, the methods described herein are performed at a temperature of equal to or greater than about 250° C. In various embodiments, the methods described herein are performed at a temperature of equal to or greater than about 255° C. In various embodiments, the methods described herein are performed at a temperature of equal to or greater than about 260° C. In various embodiments, the methods described herein are performed at a temperature of equal to or greater than about 265° C. In various embodiments, the methods described herein are performed at a temperature of equal to or greater than about 270° C. In various embodiments, the methods described herein are performed at a temperature of equal to or greater than about 275° C.

The HF can be introduced into the reaction chamber by any suitable means that enable introduction of a controlled amount of HF, and from any suitable source without limitation. For example, the HF can be introduced as pure gaseous HF or mixed with an inert carrier gas such nitrogen, argon, air, and the like. Or, for the example, the HF can be dissolved in solution, such as in an HF/pyridine solution, where the source of HF is the partial pressure of HF above the solution. Or, for example, the HF can be produced from thermal fluorination sources such as XeF₂, SF₄, or heated sodium bifluoride (NaHF₂), or from plasma sources such as NF₃ or SF₆ plasmas. The dose (amount) of HF introduced into the reaction chamber depends on the composition and thickness of the metal compound layer on the substrate, as well as the ultimate desired amount of etch per cycle in the method. In various embodiments, the dose of HF introduced into the reaction chamber is about 0.05 to about 200 Torr s. In various embodiments, the dose of HF introduced into the reaction chamber is equal to, less than, or greater than about 0.05, 0.06, 0.07, 0.08, 0.09, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 1.2, 1.4, 1.6, 1.8, 2, 2.2, 2.4, 2.6, 2.8, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 110, 120, 130, 140, 150, 160, 170, 180, 190, or about 200 Torr s. In various embodiments, the HF is introduced via a manifold. In various embodiments, the manifold includes operably connected in series: a) a precursor source (e.g., HF/pyridine), b) a diaphragm valve, c) a fill volume with pressure sensor, d) a diaphragm valve c) a flow reducing needle valve, and/or f) a particle bed. In various embodiments, the HF is anhydrous HF.

The manifold can contain additional components that facilitate introduction of HF into the reaction chamber or for other reasons that enhance or facilitate the etching process, including for commercial reasons. The diaphragm valve between the precursor source and the fill volume can be controlled on a feedback loop using the fill volume pressure sensor. The pressure in the fill volume can be maintained at any pressure between the vacuum and the vapor pressure of the precursor. In various embodiments, the control loop can maintain the pressure in the fill volume at a constant pressure of about 1, 2, 3, 4, 5, 6, 7, 8, 9, 10, 11, 12, 13, 14, 15, 16, 17, 18, 19, 20, 25, 30, 35, 40, 45, 50, 55, 60, 65, 70, 75, 80, 85, 90, 95, 100, 110, 120, 130, 140, 150, 160, 170, 180, 190, or about 200 Torr.

In various embodiments, the etching reagent includes hydrogen fluoride (HF) and a polar molecule having a dipole moment of at least 1 Debye (D). The polar molecule, in various embodiments, has at least one lone pair of electrons. In various embodiments, the polar molecule has a molecular weight is less than about 100, 110, 120, 130, 140, 150, 160, 170, 180, 190, 200, 210, 220, 230, 240, or 250 g/mol. Suitable examples of polar molecules that may be used according to the present methods include, but are not limited to ammonia (NH₃), amines (NR₁R₂R₃), alcohols (R₁OH), including polyols such as diols and triols, ethers (R₁—O—R₂), esters (R₁—C(═O)—OR₂), cyclic ethers (4-6 membered rings), cyclic esters (4-6 membered rings), cyclic aliphatic amines (4-6 membered rings), cyclic aromatic amines (4-6 membered rings), and the like. Each of R₁, R₂, and R₃ is independently hydrogen or C₁₋₆ alkyl.

Polar molecules can include polar aprotic and/or polar protic molecules, such as polar aprotic solvents and/or polar protic solvents. Aprotic molecules cannot donate protons, therefore cannot form hydrogen bonds. Protic molecules have acidic hydrogens, therefore can act as proton donors to form hydrogen bonds. Examples of suitable polar aprotic molecules include, without limitation, formamide (3.73 D), N-methylformamide (3.83 D), diethyl ether (1.15 D), dichloromethane (1.6 D), tetrahydrofuran (1.75 D), ethyl acetate (1.78 D), acetone (2.88 D), dimethylformamide (3.82 D), acetonitrile (3.92 D) and dimethyl sulfoxide (3.96 D), propylene carbonate (4.9 D), where the number in the parentheses refers to the dipole moment of the molecule.

Examples of suitable polar protic molecules include, without limitation, ammonia (1.40 D), methyl amine (1.31 D), dimethyl amine (1.01 D), ethylamine (1.22 D), pyridine (2.22), aniline (1.51 D), ethylenediamine (1.99 D), t-butanol (1.70 D), n-propanol (1.68 D), ethanol (1.69 D), methanol (1.70 D), acetic acid (1.74 D), formic acid (1.41 D), ethylene glycol (2.28 D), and water (1.85 D), where the number in the parentheses refers to the dipole moment of the molecule.

In various embodiments, the polar molecule is NH₃. The polar molecule can be introduced directly, such as for example ammonia gas, or indirectly via thermal decomposition of ammonium salts such as NH₄F.

In various embodiments, the amount of polar molecule introduced into the reaction chamber is about 0.05 to about 200 Torr s. In various embodiments, the dose of the polar molecule introduced into the reaction chamber is equal to, less than, or greater than about 0.05, 0.06, 0.07, 0.08, 0.09, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 1.2, 1.4, 1.6, 1.8, 2, 2.2, 2.4, 2.6, 2.8, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 110, 120, 130, 140, 150, 160, 170, 180, 190, or about 200 Torr s.

Additionally, in various embodiments, the polar molecule and HF can arise from the same source, such as for example heating NH₄F to produce NH₃ and HF. Without being bound by theory, the polar molecule acts as a solvent to solvate HF and stabilize the dissociation products H⁺ and F⁻. The polar molecule can also act as a solvent to stabilize the reaction product of F⁻ with HF, which forms HF₂⁻. In various embodiments, the amount of polar molecule (for example its mole fraction) is greater than the amount of HF in the reaction chamber. In various embodiments, the ratio of HF:polar molecule can be other than 1:1, for example the ratio can be about 1:1, 1:2, 1:3, 1:5, 1:10, 1:20 or 1:x, where x is greater than 20. In various embodiments, the ratio of polar molecule:HF can be about 1:1, 1:2, 1:3, 1:5, 1:10, 1:20 or 1:x, where x is greater than 20.

In various embodiments, the exposure time of the substrate to the etching reagent for each exposure is independently 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 130, 140, 150, 160, 170, 180, 190, 200, 210, 220, 230, 240, 250, 260, 270, 280, 290, 300, 310, 320, 330, 340, 350, or 360 seconds. In various embodiments, the exposure time is about 30 to about 60 seconds. In various embodiments, the number of exposures of the substrate to the etching reagent is 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, or more exposures.

Surprisingly and unexpectedly, it was found that at least 50:1, 60:1, 70:1, 80:1, 90:1, 100:1, or greater selectivity for SiNₓ removal over SiO₂ retention was obtained with the methods described herein when anhydrous HF was used as the etching agent. Selective SiNₓ etching can find application in, for example, lateral SiNₓ etching to form discontinuous charge trap nitride layers in 3D vertical NAND flash memory cells. Surprisingly and unexpectedly, it was found that least a 1000:1, 1500:1, 2000:1, 2500:1, 3000:1, 4000:1, 5000:1, or greater selectivity for SiO₂ removal over SiNₓ retention was obtained when HF was co-dosed with NH₃. Selective SiO₂ etching can find application in, for example, complete SiO₂ removal in high-aspect-ratio self-aligned contact (SAC) architectures. In various embodiments, no blocking layer or layers are deposited on SiO₂ prior to etching SiNₓ. In various embodiments, no blocking layer or layers are deposited on SiNₓ prior to etching SiO₂. In various embodiments, the etching reagent also includes an alkyl aluminum species, AlR₃, where R is C₁₋₄ alkyl. In various embodiments, the alkyl aluminum species is Al(CH₃)₃ (TMA).

### EXAMPLES

Various embodiments of the present application can be better understood by reference to the following Examples which are offered by way of illustration. The scope of the present application is not limited to the Examples given herein.

All experiments were conducted at a fixed temperature of 275° C. This setting was above the transition temperature between thermal atomic layer deposition (ALD) of AlF₃ below 250° C. and thermal ALE of Al₂O₃ above 250° C. 275° C. was also above the thermal desorption temperature of ammonium hexafluorosilicate ((NH₄)₂SiF₆) salt that can form during spontaneous etching of both SiNₓ and SiO₂. In addition, 275° C. was below the decomposition temperature of TMA around 300° C.

### Vacuum Reactor, Reactants, and Thin Film Samples

Thermal ALE and spontaneous etching experiments were conducted in a V-shaped, hot-wall, viscous-flow reactor. Detailed descriptions and a computer-aided design cross-section of this apparatus have been published previously. A rotary vane pump (Pascal 2010 C1, Pfeiffer Vacuum) evacuated reactants, reaction byproducts, and purge gas. The vacuum system maintained a base pressure in the 10 mTorr range. A capacitance manometer (AA09A11TCE0 Baratron®, MKS Instruments) monitored the total pressure in the vacuum chamber. Samples were heated through the hot reactor walls. A temperature controller (2604, Eurotherm) maintained the sample temperature at 275° C.

Before each etching experiment, the stainless-steel reactor walls and sample holder were coated with ˜10 nm of Al₂O₃ using 100 ALD cycles of TMA (98% purity, Strem) at 1.5 Torr for 15 s and H₂O (HPLC grade, Fisher Chemical™) at 3 Torr for 30 s. Evacuation and purge steps separated these reactant exposures. A linear Al₂O₃ growth per cycle of ˜1 Å was consistent with previous literature benchmarks. For a few experiments, designed to obtain better H₂O-free conditions during fluorination, the reactor walls and sample holder were coated with ZrF₄. First, 10 ALD cycles of tetrakis(ethylmethylamino) zirconium (IV) (TEMAZ, 99% purity, Strem; kept at 110° C.) at 1.5 Torr for 15 s and H₂O at 3 Torr for 30 s deposited a few monolayers of ZrO₂. Then, the ultra-thin ZrO₂ ALD film was fluorinated into ZrF₄ using 30 static exposures of HF⁻ pyridine at 3 Torr for 45 s. After the reactor wall coating, a fresh sample was loaded and pre-heated for 30 min. Thermal ALE alternated between TMA and the fluorinating agents for 25 cycles. Spontaneous etching repeated 25 fluorination exposures consecutively.

Anhydrous HF vapor was obtained from a solution of ˜70 wt. % HF in ˜30 wt. % pyridine (Sigma-Aldrich). TMA and HF-pyridine were kept at room temperature. A co-dose of HF+NH₃ was derived from heating NH₄F (≥99.99% trace metals basis, Sigma-Aldrich) to 130° C. Since NH₄F is hygroscopic, absorbed H₂O was thoroughly evacuated by pumping on the heated salt through the reactor.

Every reactant exposure consisted of the following successive steps: First, a 45 s interval evacuated the reactor down to base pressure. A closed angular bellows valve then separated the reactor from the pump. Subsequently, the reactant vapor was drawn into the reactor and statically exposed to the sample surface at a total pressure of 3 Torr for a duration of 45 s. The open angular bellows valve then re-connected the reactor with the pump for a 15 s evacuation interval plus a 120 s purge step with 150 sccm argon (Ar, ultra-high purity, Airgas). The reactant sequence, exposure times, and pressures, as well as evacuation and purge steps, were precisely controlled and recorded by a virtual interface (VI) programmed in LabVIEW version 19.0.1f5 (National Instruments™).

SiO₂ samples were purchased from Silicon Valley Microelectronics. Wet-thermal oxidation was used to grow an initial SiO₂ film thickness of ˜500 nm on single-side-polished, boron-doped <100> Si wafers. SiNₓ samples were prepared and provided by Tokyo Electron (TEL). Plasma-enhanced chemical vapor deposition (PE-CVD) was used to deposit an initial SiNₓ film thickness of ˜300 nm on 300 mm double-side-polished Si wafers.

The SiNₓ film thickness and optical parameters were determined ex situ by variable angle spectroscopic ellipsometry (VASE; cf. Supporting Information) with an M-2000® (J.A. Woollam Co.) in the ultraviolet (UV) and visible (VIS) wavelength range from 240 to 1,000 nm. One Tauc-Lorentz oscillator, together with a UV pole, sufficiently parameterized the SiNₓ layer. The measured refractive index between 2.1 and 2.5 matched the reported value of 2.4 at 248 nm for a Si-rich PE-CVD SiN_{0.67} antireflective coating (ARC) with ˜22 at. % hydrogen content. In addition, significant observed UV+VIS absorption has been attributed to the formation of Si—Si bonds.

The chemical composition of as-received SiO₂ and SiNₓ samples was characterized by x-ray photoelectron spectroscopy (XPS; cf. Supporting Information) in a PHI 5600 system (RBD Instruments) with monochromatic Al Kα x-ray source (1486.6 eV). XPS spectra were analyzed in CasaXPS software version 2.3.25. XPS confirmed a near stoichiometric composition of SiO₂ and a Si-rich composition of SiNₓ with x˜0.8. Furthermore, the XPS Si 2p peak position and width of SiNₓ suggested Si atoms in a chemical environment of both Si—N and Si—Si bonds.

### In Situ Spectroscopic Ellipsometry Studies

An in situ spectroscopic ellipsometry instrument (iSE, J.A. Woollam Co.) was mounted on the reactor at an incidence angle of ˜70° to monitor thickness changes during thermal ALE or spontaneous etching. Samples were hand-diced into coupons (0.5 in x 0.5 in) mounted on a horizontal stage with stainless-steel clips, and dusted off with Ar gas. Although the ellipsometer monitored one individual thin film in the reactor at a time, all experiments were conducted under identical conditions. Ellipsometric spectra in the wavelength range from 400 to 1,000 nm were acquired after each reactant exposure by integrating over 5 s at the end of the Ar purge step.

The transparent SiO₂ or SiNₓ film thicknesses between 100 and 500 nm enabled an interference enhancement. The interference enhancement improved the signal-to-noise ratio toward a confidence interval of ±0.01 Å. This confidence interval was determined as the single standard deviation of 30 repeated iSE measurements of the initial film thickness. Thicknesses were shifted to start at zero for each experimental subset. A steady-state etching regime was usually established on each initial, pristine surface within five ALE cycles or five consecutive HF or HF+NH₃ exposures. The last 20 of a series of 25 data points were linearly interpolated. The slope of the line determined the corresponding EPC or spontaneous etch rate β. ALE synergy and selectivity factors were calculated according to Equations (1) and (2).

All optical modeling was performed in CompleteEASE software version 6.57 (J.A. Woollam Co.). SiO₂ samples were modeled as a layer stack of the SiO₂_JAW| 10 Å INTR_JAW| Si Temp JAW (275° C.) material files from the CompleteEASE library. SiNₓ samples were modeled by stacking a SiNₓ layer on top of 25 Å INTR_JAW| Si Temp JAW(275° C.). The optical parameters of this SiNₓ layer were extracted from ex situ VASE measurements. Surface roughness was included on top of both the layer stacks. CompleteEASE modeled this surface roughness as a Bruggeman effective medium approximation (B-EMA) layer, mixing 50% of the film material with 50% void. The surface roughness was carefully monitored but usually exhibited no significant change unless stated otherwise.

### SiO₂ Thermal ALE Using TMA/HF and Synergy Factor

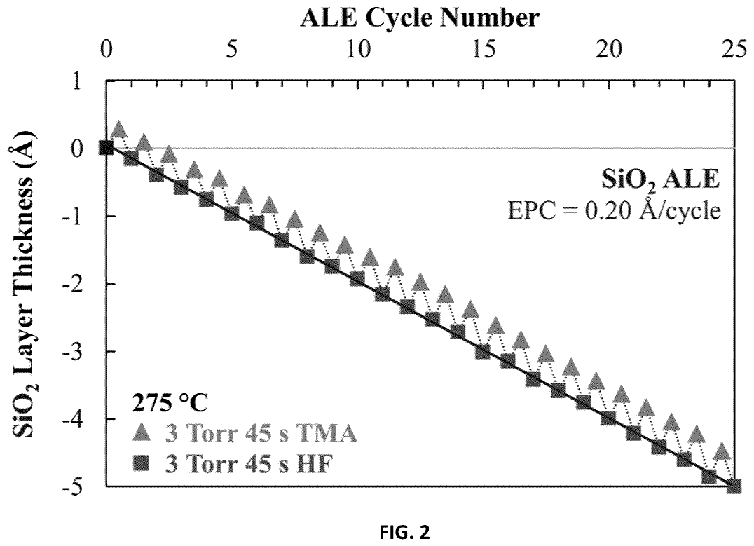

FIG. 2 shows the changes in SiO₂ layer thickness during the TMA/HF ALE sequence at 275° C. Each data point represents a single static exposure of 3 Torr for 45 s. The SiO₂ thickness decreased linearly versus ALE cycle number. The thick solid line linearly interpolates data points after HF exposures, i.e., after complete ALE cycles. This linear fit corresponded to an EPC of 0.20 Å/cycle. The linear thickness loss suggested that sequential TMA and HF exposures effectively removed SiO₂. The EPC was consistent within a range from 0.20 to 0.35 Å/cycle from previous reports for SiO₂ thermal ALE at 300 to 350° C.

The thickness changes observed in FIG. 2 with half-cycle resolution may be understood as convoluted effects on the geometrical thickness or refractive index of the SiO₂ film or its surface. Alkyl groups are highly polarizable as known by their high Raman cross sections. Consequently, ellipsometry can sensitively detect their adsorption or removal. During TMA exposures, ligand exchange volatilizes a fluorinated surface layer and converts the underlying SiO₂ film surface. TMA also adsorbs methyl surface species. In this case, the polarizability from adsorbing methyl groups might obscure a thickness loss from the ligand-exchange reaction. During HF exposures, HF removes previously adsorbed surface species and fluorination changes the refractive index of the AlSiₓO_{y} conversion layer. The effective optical thickness loss after HF exposures may be primarily attributed to the removal of methyl surface species.

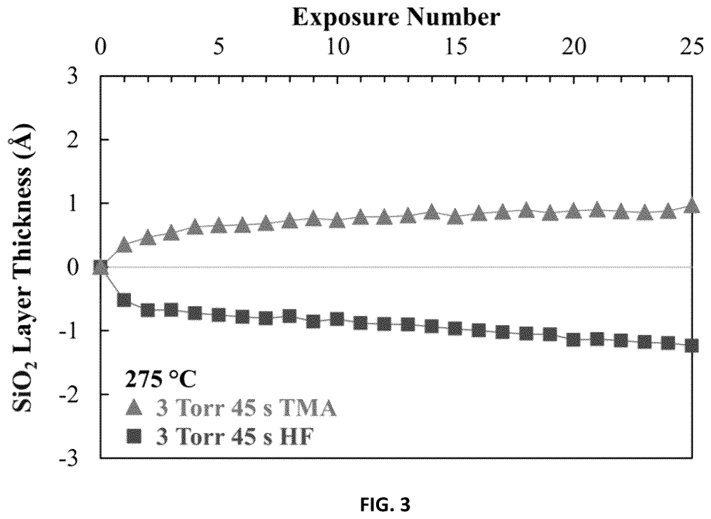

FIG. 3 plots the SiO₂ layer thickness during a series of 25 consecutive static exposures of only TMA or HF by themselves, with the same scale as FIG. 2. The first exposure in each series was equivalent to a single TMA or HF exposure during the thermal ALE cycles shown in FIG. 2. Consecutive TMA exposures in FIG. 3 exhibited a small thickness gain instead of a thickness loss. The TMA half-reaction self-terminated almost entirely within three consecutive exposures. This self-limiting thickness gain was consistent with the saturation of the methyl surface coverage. Beyond five exposures, a marginal linear increase continued over 20 exposures at a slope of +0.02 Å per TMA exposure. Since this insignificant increase indicated no undesired etch contribution, α_{TMA} was neglected as zero.

Consecutive HF exposures in FIG. 3 exhibited a slight thickness loss. The HF half-reaction self-limited within two consecutive exposures, consistent with effectively removing previously adsorbed methyl groups. Beyond five exposures, a slight thickness decrease continued linearly over 20 exposures with 0.02 Å per 45 s HF exposure. This slight, linear thickness loss signified minor spontaneous etching at β_{HF}=0.03 Å/min.

The results in FIG. 3 for negligible etching of SiO₂ by HF were consistent with previous studies concluding that anhydrous HF vapor alone cannot etch SiO₂. However, SiO₂ etching has been observed when H₂O vapor was present together with HF. H₂O is believed to facilitate the formation of HF₂⁻ active etch species from HF that can etch SiO₂ as herein. Consequently, β_{HF} was attributed to a small amount of H₂O that might form during the fluorination of the Al₂O₃ reactor wall coating. Spontaneous etching of SiO₂ would then itself produce more H₂O through the reaction: SiO₂+4·HF(g)→SiF₄(g)+2·H₂O(g).

FIG. 2 and FIG. 3 provide the information needed to evaluate the synergy factor. The linear EPC of 0.20 Å/cycle was considerably greater than a minor, undesired spontaneous etching component of 0.02 Å per HF exposure. A synergy factor of 88% signified that SiO₂ thermal ALE was reasonably ideal at 275° C. Additional experiments improved this moderate ALE synergy up to 95% by using ZrF₄ as reactor wall passivation instead of an Al₂O₃ ALD coating. ZrF₄ passivation leads to better H₂O-free conditions during the HF reaction. ZrF₄ avoids the evolution of H₂O that can occur with Al₂O₃ according to: Al₂O₃+6·HF→2·AlF₃+3·H₂O. TMA also removes the AlF₃ surface layer, thereby restoring Al₂O₃ on the walls to release H₂O during every HF exposure. In contrast, ZrF₄ resists reaction with TMA to passivate the reactor walls.

### SiNₓ Thermal ALE Using TMA/HF and Synergy Factor

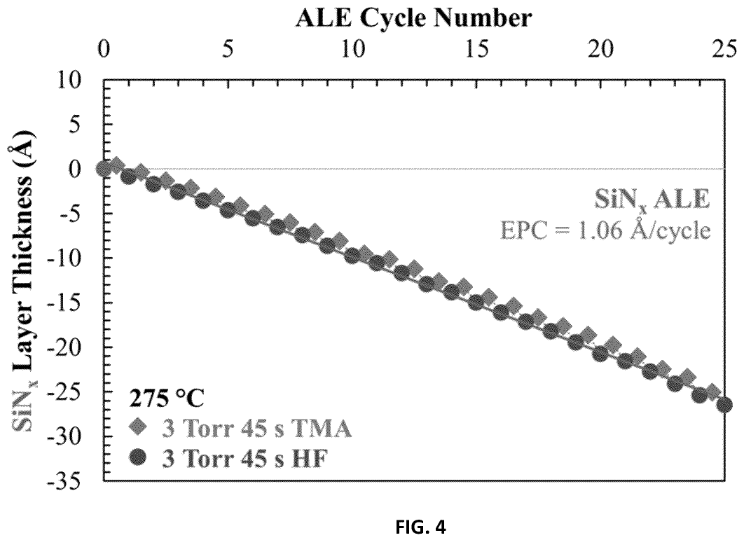

FIG. 4 presents the SiNₓ layer thickness versus ALE cycle number for thermal ALE using TMA and HF at 275° C. Each data point represents a single static exposure of 3 Torr for 45 s. The SiNₓ thickness decreased linearly versus ALE cycles. The thick solid line linearly interpolates the data points after HF exposures. The linear fit was consistent with an EPC of 1.06 Å/cycle. The significant linear thickness loss suggested that sequential TMA and HF exposures effectively removed SiNₓ.

This result for SiNₓ thermal ALE was unexpected compared with earlier work that required an oxidation step to obtain Si₃N₄ thermal ALE. The pulse sequence here did not include an oxidation step. HF exposures were 8 Torres in the earlier experiments. These HF exposures were significantly lower than the HF exposures of 135 Torres in the current studies. In addition, the previously studied Si₃N₄ films were prepared by low-pressure chemical vapor deposition (LP-CVD, University Wafer). The LP-CVD Si₃N₄ was near-stoichiometric with a hydrogen content below 3 at. %.

The composition of LP-CVD Si₃N₄ varied substantially from the SiNₓ films investigated here that were prepared by plasma-enhanced CVD (PE-CVD). XPS analysis revealed that the PE-CVD SiNₓ film was Si-rich with x˜0.8. In addition, PE-CVD SiNₓ probably contained a considerable amount of hydrogen. The contrasting observations between the current SiNₓ ALE experiments and previous Si₃N₄ ALE experiments may be partially attributed to the spontaneous etching of Si-rich SiNₓ at higher HF exposures.

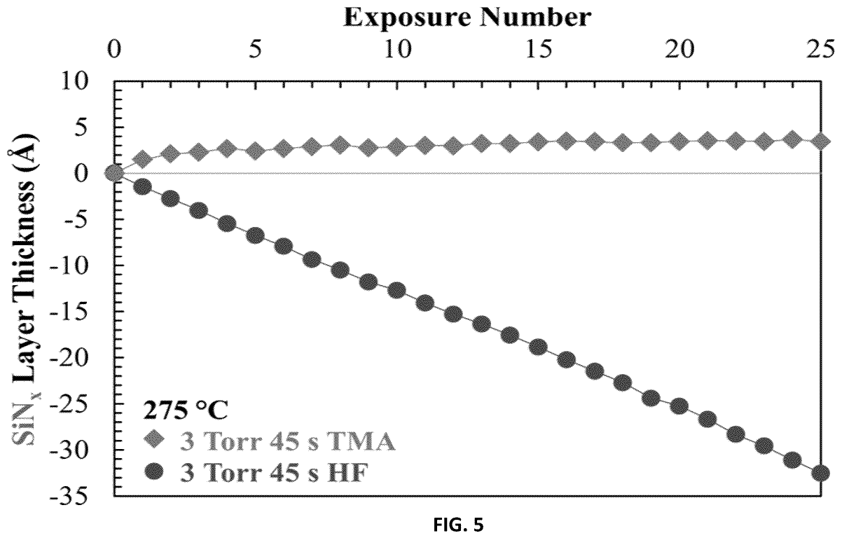

FIG. 5 plots the SiNₓ layer thickness during a series of 25 consecutive static exposures of only TMA or HF by themselves, with the same scale as FIG. 4. The first exposure in each series was equivalent to a single TMA or HF exposure during the ALE cycles shown in FIG. 4. Consecutive TMA exposures in FIG. 5 exhibited a thickness gain instead of a thickness loss. The TMA half-reaction self-terminated almost entirely within two consecutive exposures, consistent with the saturation of the methyl surface coverage. Beyond five exposures, a marginal linear increase continued over 20 exposures at a slope of +0.05 Å per TMA exposure. α_{TMA} was neglected as zero.

In contrast, consecutive HF exposures in FIG. 5 did not exhibit self-limiting behavior. The SiNₓ thickness decreased linearly during all 25 HF exposures. This continuous linear thickness loss produced a spontaneous etch rate of 1.29 Å per 45 s HF exposure or β_{HF}=1.72 Å/min. These results indicated that HF exposures spontaneously etched SiNₓ at 275° C. This major spontaneous etching explains the high EPC for SiNₓ thermal ALE in FIG. 4. The spontaneous etching of stoichiometric silicon nitride by HF may occur as: Si₃N₄ (s)+12·HF(g)→3·SiF₄(g)+4·NH₃(g).

FIG. 4 and FIG. 5 provide the information needed to evaluate the synergy factor. The spontaneous etching at 1.29 Å per HF exposure was greater than the EPC of 1.06 Å/cycle for SiNₓ thermal ALE. Consequently, Equation (1) calculated a synergy factor of −22%. This negative value indicated that SiNₓ spontaneous etching predominated over the ALE sequence when using anhydrous HF vapor at 275° C.

Selectivity Between Al₂O₃, SiO₂ and SiNₓ Thermal ALE Using TMA/HF

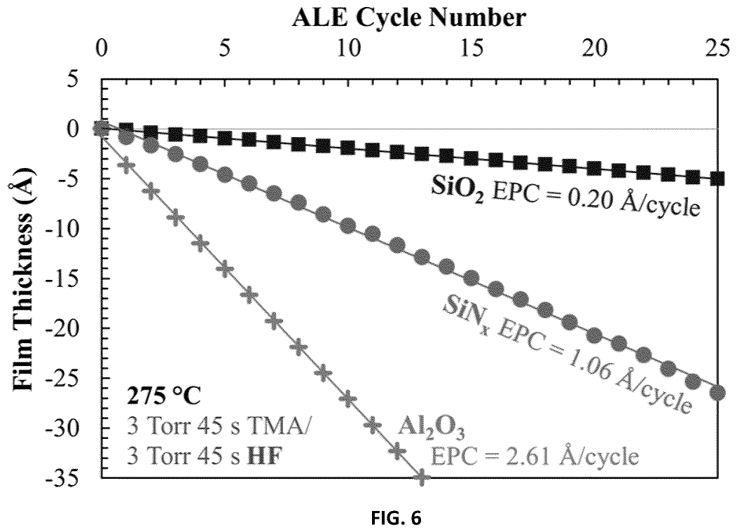

FIG. 6 compares SiO₂ and SiNₓ thermal ALE with sequential TMA and HF exposures of 3 Torr for 45 s at 275° C. These results were shown earlier on FIG. 2 and FIG. 4. FIG. 6 also includes results for thermal ALE of an Al₂O₃ ALD film at 275° C. for comparison. Al₂O₃ thermal ALE using TMA and HF as the reactants is included because this system is the model thermal ALE process. Each sample was monitored individually but under identical process conditions. The Al₂O₃, SiO₂, and SiNₓ film thicknesses all decreased linearly with progressing ALE cycles.

FIG. 6 reveals that the slopes of the linear thickness losses versus ALE cycle number were different for each material. The EPCs were 2.61, 1.06 and 0.20 Å/cycle for Al₂O₃, SiNₓ, and SiO₂, respectively. The EPC for Al₂O₃ thermal ALE was consistent with previous reports ranging from 0.14 to 2.50 Å/cycle at reactant pressures from 40 mTorr to 5 Torr and temperatures between 250 and 300° C. The EPC for SiO₂ thermal ALE was also consistent with previous works. The EPC for SiNₓ thermal ALE was much larger than in previous work for Si₃N₄ thermal ALE at lower HF exposures.

Equation (2) was used to determine a moderate selectivity factor of ˜5:1 for preferential etching of SiNₓ compared to SiO₂. However, SiNₓ thermal ALE exhibited no synergy because the spontaneous etching of SiNₓ during HF exposures was not self-limiting. Larger HF exposures would continue to increase the selectivity factor because the HF exposure during SiNₓ thermal ALE is not self-limiting.

Selectivity Between SiO₂ and SiNₓ Spontaneous Etching Using HF Alone

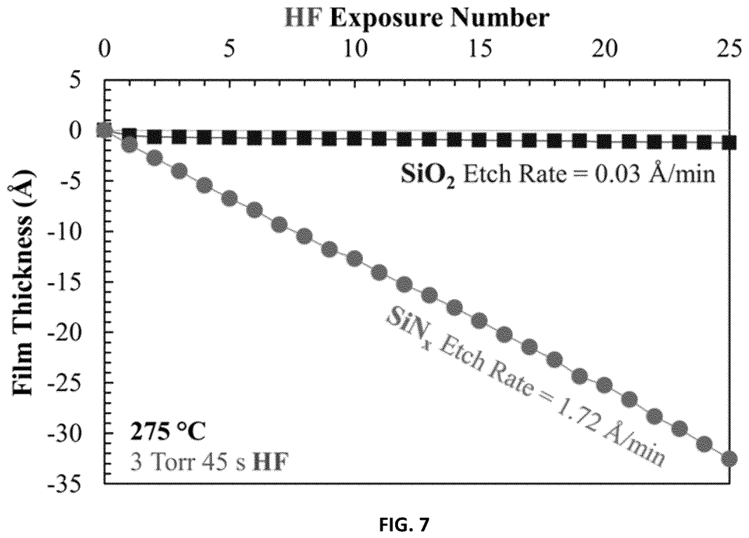

FIG. 7 shows the film thickness versus HF exposure number to compare the selectivity between SiO₂ and SiNₓ for spontaneous etching using only HF exposures. Each sample was monitored individually under identical process conditions for a series of 25 consecutive static HF exposures at 3 Torr for 45 s. These results were shown earlier on FIG. 3 and FIG. 5. The SiO₂ film thickness decreased slightly with consecutive HF exposures at an etch rate of 0.03 Å/min. This negligible SiO₂ etching was consistent with previous literature. In contrast, the SiNₓ film thickness decreased linearly with consecutive HF exposures at an etch rate of 1.72 Å/min. The spontaneous etch rate of SiNₓ was much larger than the SiO₂ etch rate.

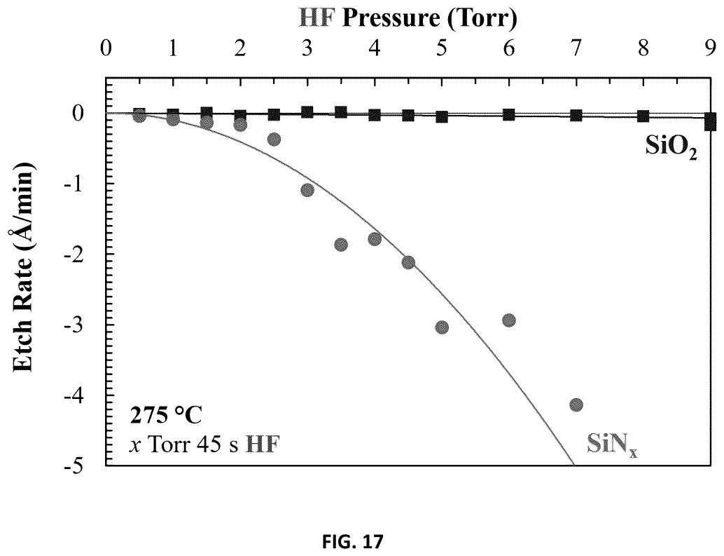

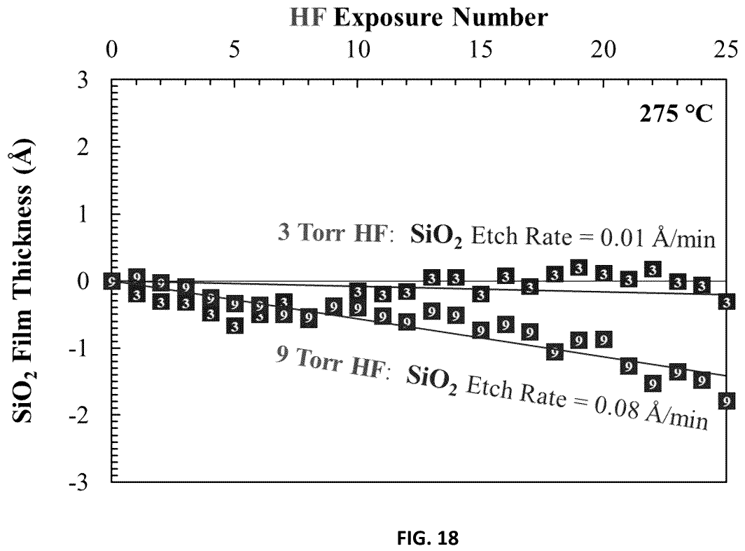

Equation (2) calculated a significantly higher selectivity factor of ˜50:1 for SiNₓ etching compared to SiO₂ etching. FIG. 17 shows that larger HF exposures continued to increase the selectivity factor up to ˜150:1 at 9 Torr. Ensuring H₂O-free conditions during HF exposures improved this high selectivity even further. After coating the reactor walls and sample holder with ZrF₄ to obtain better H₂O-free conditions during fluorination, FIG. 18 shows de-facto SiO₂ non-etch using 3 and 9 Torr anhydrous HF vapor, respectively, at 275° C. A literature report for wet etching employing an organic solution with 10 mass % anhydrous HF at 80° C. has shown that selectivity for spontaneous etching of SiNₓ over SiO₂ was highest at 15:1 under H₂O-free conditions.

SiO₂ Thermal ALE Using TMA/HF+NH₃ Co-Dosing and Synergy Factor

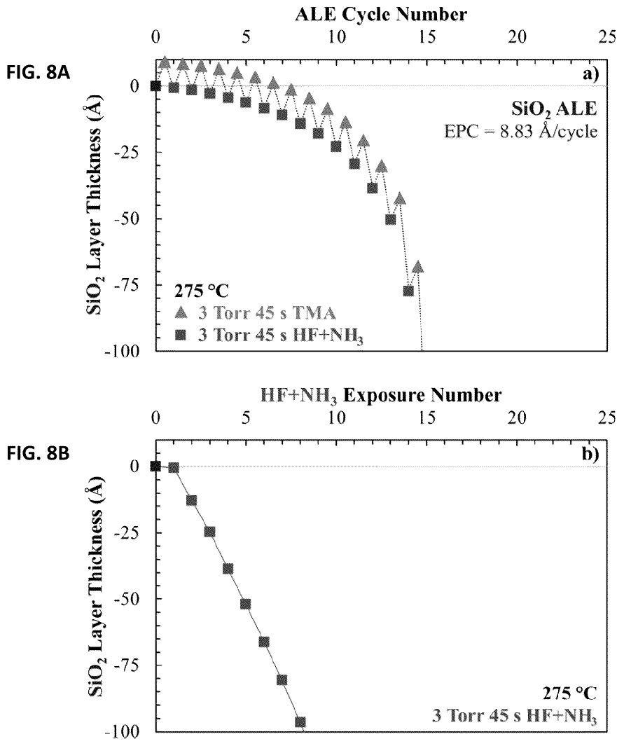

The effect of NH₃ co-dosing during the HF exposures was examined to determine if coadsorbates could change the nature of the active etching species and influence the ALE synergy and selectivity. FIG. 8A displays the changes in SiO₂ layer thickness during the thermal ALE sequence that cycled between separate exposures of TMA and HF+NH₃ co-dosing at 275° C. HF+NH₃ co-dosing was obtained from evaporating NH₄F salt at 130° C. Each single static exposure was 3 Torr for 45 s. The SiO₂ thickness decreased substantially versus ALE cycle number. A thickness loss of 132.44 Å was measured after 15 ALE cycles. Dividing this thickness loss by 15 ALE cycles yields an average EPC of 8.83 Å/cycle. In addition, the SiO₂ surface roughness increased noticeably with every ALE cycle. The large EPC with significant surface roughening suggested that rapid spontaneous etching of SiO₂ occurred during this SiO₂ thermal ALE process with HF+NH₃ co-dosing.

To check for spontaneous etching, a SiO₂ film was examined under the same HF+NH₃ co-dosing conditions as employed in FIG. 8A. FIG. 8B shows the SiO₂ layer thickness during a series of 25 consecutive static HF+NH₃ co-dosing exposures, with the same scale as FIG. 8A. The large thickness decrease continued beyond the eight HF+NH₃ exposures shown in FIG. 8B. The thickness loss was 515.61 Å after 25 consecutive HF+NH₃ exposures. Dividing this thickness loss by 25 exposures yields an average etch rate of 20.62 Å per 45 s HF+NH₃ exposure or β_{HF+NH}_{₃}=27.50 Å/min.

Co-dosing HF+NH₃ opened a new pathway for rapid spontaneous etching of SiO₂ compared to exposing HF vapor by itself without NH₃ co-dosing. The spontaneous etching component at 20.62 Å per HF+NH₃ exposure was greater than the EPC of 8.83 Å/cycle during SiO₂ thermal ALE with HF+NH₃ co-dosing. These results indicated that TMA exposures slowed down the rapid SiO₂ spontaneous etching during the HF+NH₃ co-dosing. Equation (1) calculated a synergy factor of −134% for SiO₂ thermal ALE with HF+NH₃ co-dosing. This negative value indicated that rapid spontaneous etching of SiO₂ predominated over the ALE sequence when co-dosing HF+NH₃ at 275° C.

SiO₂ Spontaneous Etching Co-Dosing DMA (dimethyl amine)+HF

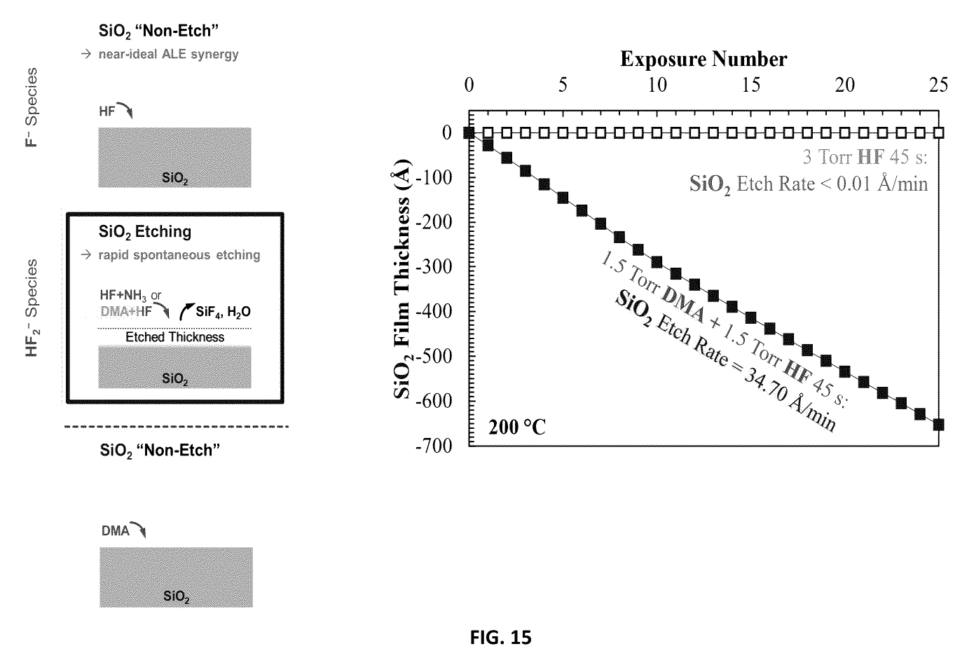

The effect of DMA co-dosing during HF exposures was examined to determine if other polar coadsorbates could likewise change the nature of the active etching species and influence the selectivity. FIG. 15 displays the changes in SiO₂ layer thickness during consecutive exposures of anhydrous HF vapor alone (open symbols) versus DMA+HF co-dosing (closed symbols) at 200° C. Each single static exposure consisted of either 3 Torr HF or of 1.5 Torr DMA plus 1.5 Torr HF for 45 s. In the case of anhydrous HF exposures, the SiO₂ thickness remained basically constant. The SiO₂ etch rate by anhydrous HF vapor was below 0.01 Å/min. In the case of DMA+HF co-dosing exposures, the SiO₂ thickness decreased substantially versus DMA+HF exposure number. The SiO₂ etch rate by DMA+HF co-dosing was 34.70 Å/min.

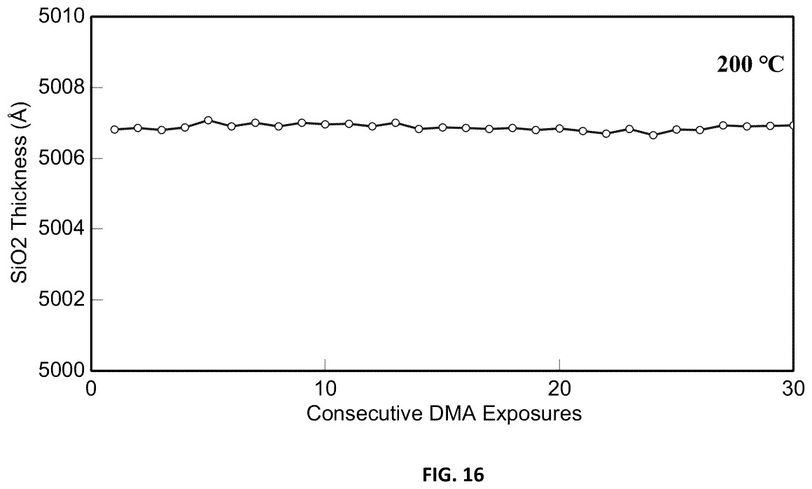

Co-dosing DMA+HF likewise opened the new pathway for rapid spontaneous etching of SiO₂ compared to exposing HF vapor by itself without DMA co-dosing. These results indicated that DMA, and perhaps polar molecules in general, can serve as alternative coadsorbates to produce HF₂⁻ species for SiO₂ spontaneous etching. Noteworthy, FIG. 16 displays no change in SiO₂ layer thickness during consecutive exposures of DMA alone. This demonstrated that neither anhydrous HF vapor alone nor DMA alone etched SiO₂ at 200° C.”

SiNₓ Thermal ALE Using TMA/HF+NH₃ Co-Dosing and Synergy Factor

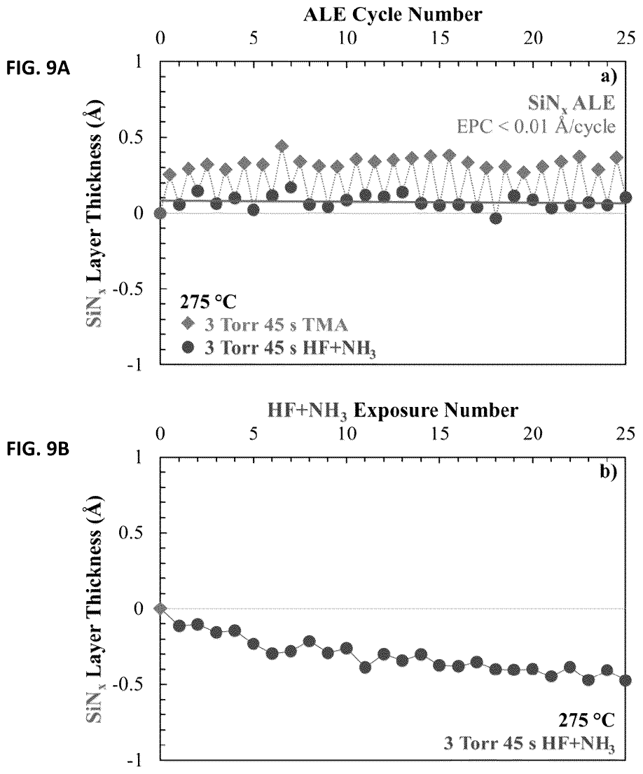

The effect of NH₃ co-dosing during HF exposures was also examined on SiNₓ films. FIG. 9A displays the changes in SiNₓ layer thickness during the TMA/HF+NH₃ ALE sequence at 275° C. Each single static exposure was 3 Torr for 45 s. The SiNₓ thickness remained virtually constant versus ALE cycle number. The thick solid line linearly interpolates data points after HF+NH₃ exposures, i.e., after complete ALE cycles. This linear fit was consistent with an EPC smaller than the confidence interval of +0.01 Å/cycle. The thickness retention indicated that sequential TMA and HF+NH₃ exposures cannot etch SiNₓ. The oscillations in SiNₓ layer thickness were attributed to surface methyl groups being added by TMA and removed by HF exposures.

FIG. 9B explores the possibility for spontaneous etching of SiNₓ by 25 consecutive static exposures of HF+NH₃ co-dosing. The first exposure in this series was equivalent to a single HF+NH₃ exposure during SiNₓ thermal ALE shown in FIG. 9A. Consecutive HF+NH₃ exposures in FIG. 9B exhibited a marginal thickness decrease with a spontaneous etch rate of 0.01 Å per 45 s HF+NH₃ exposure or β_{HF+NH}_{₃}=0.02 Å/min. Co-dosing HF+NH₃ dramatically stopped the spontaneous etching of SiNₓ compared to the large spontaneous etch rate β_{HF} monitored in FIG. 5 when using HF exposures without NH₃.

Both the negligible EPC and β_{HF+NH}_{₃} indicated that co-dosing HF+NH₃ dramatically restricted the spontaneous etching of SiNₓ compared to the large SiNₓ removal observed using HF exposures without NH₃ in FIG. 5. SiNₓ resisted thermal ALE and spontaneous etching when co-dosing HF+NH₃. Therefore, calculating a synergy factor was not meaningful. SiNₓ had no direct etch pathway through conversion, fluorination, and ligand exchange when HF+NH₃ co-dosing restricted the spontaneous etching of SiNₓ.

Selectivity Between SiO₂ and SiNₓ Thermal ALE Using TMA/HF+NH₃ Co-Dosing

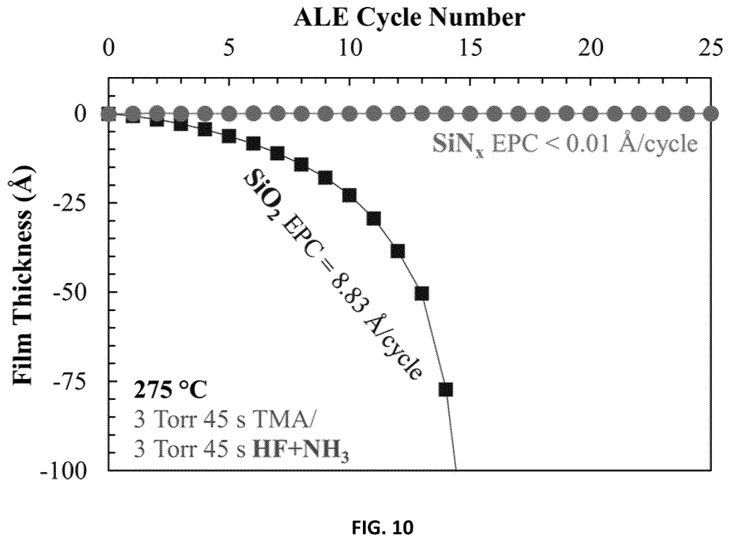

Given that SiNₓ thermal ALE and SiNₓ spontaneous etching were both negligible with HF+NH₃ co-dosing, the selectivity between SiO₂ and SiNₓ was expected to be high. FIG. 10 directly compares the SiO₂ and SiNₓ film thicknesses versus ALE cycle number. The EPC was 8.83 Å/cycle for SiO₂ thermal ALE with HF+NH₃ co-dosing from FIG. 8A. In contrast, the EPC remained below the confidence limit of +0.01 Å/cycle for SiNₓ thermal ALE with HF+NH₃ co-dosing from FIG. 9A.

Based on the results in FIG. 10, Equation (2) calculated an exceptionally high selectivity factor >1000:1 for SiO₂ etching compared to SiNₓ etching for thermal ALE using sequential exposures of TMA and HF+NH₃ co-dosing. This exceptional selectivity for preferential SiO₂ removal with HF+NH₃ co-dosing was reversed compared to the ˜5:1 selectivity for preferential SiNₓ removal observed in FIG. 6 without HF+NH₃ co-dosing.

Selectivity Between SiO₂ and SiNₓ Spontaneous Etching Co-Dosing HF+NH₃

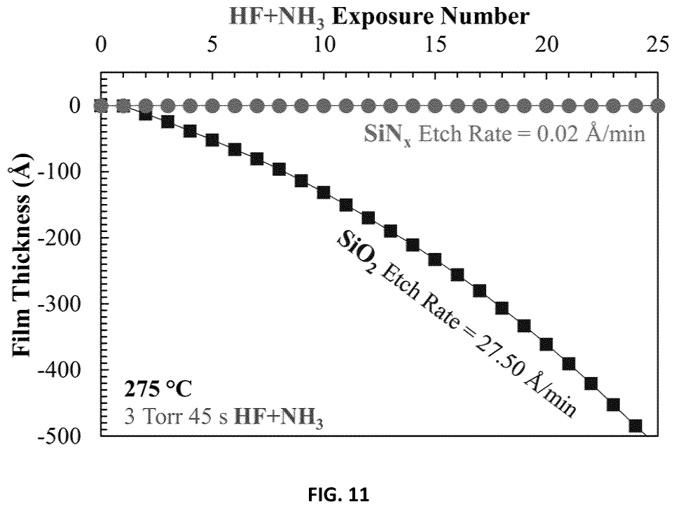

FIG. 11 shows the selectivity between SiO₂ and SiNₓ for spontaneous etching using HF+NH₃ co-dosing. The etch rate was 27.50 Å/min for SiO₂ spontaneous etching with HF+NH₃ co-dosing partially from FIG. 8B. In contrast, the etch rate of 0.02 Å/min was negligible for SiNₓ spontaneous etching with HF+NH₃ co-dosing from FIG. 9B.

Based on these dramatically different etch rates, Equation (2) calculated a high selectivity factor of >1000:1 for SiO₂ etching compared to SiNₓ etching for spontaneous etching using HF+NH₃ co-dosing. This exceptional selectivity for preferential SiO₂ removal with HF+NH₃ co-dosing was reversed compared to the selectivity for preferential SiNₓ removal observed in FIG. 7 without NH₃ co-dosing. These results illustrated that the NH₃ coadsorbate played a key role in dictating the etch selectivity.

### Etch Species During HF Exposures and HF+NH₃ Co-Dosing Exposures

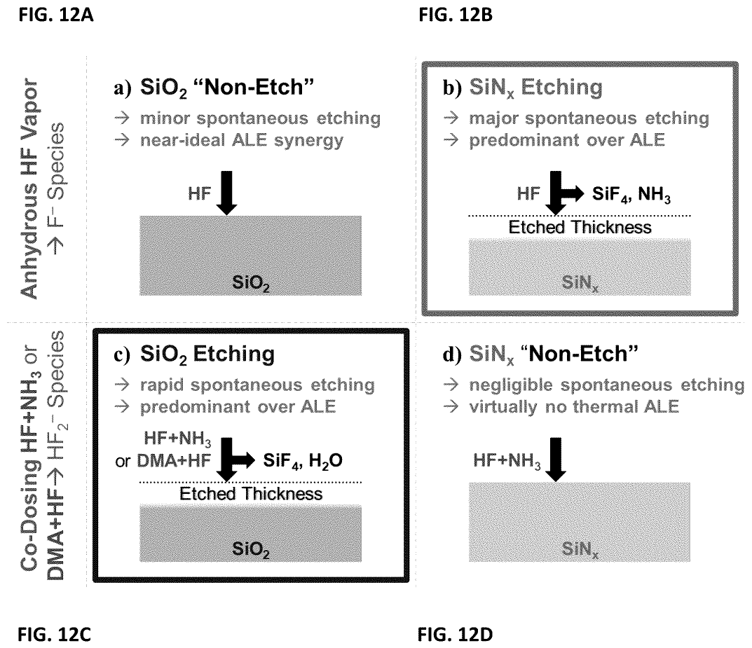

FIG. 12 summarizes all the spontaneous etching scenarios explored in this paper. The top row addresses anhydrous HF vapor alone. FIG. 12A illustrates SiO₂ “non-etch” by HF, resulting in near ideal synergy for SiO₂ thermal ALE using TMA and HF. In contrast, FIG. 12B highlights the major SiNₓ spontaneous etching by HF, predominating over the respective ALE sequence. The bottom row addresses HF+NH₃ co-dosing. FIG. 12C highlights the rapid SiO₂ spontaneous etching by HF+NH₃ or DMA+HF, predominating over the respective ALE sequence. FIG. 12D illustrates the SiNₓ “non-etch” by HF+NH₃, resulting in virtually no SiNₓ thermal ALE using TMA and HF+NH₃, as well as negligible SiNₓ spontaneous etching using HF+NH₃ co-dosing.

The SiO₂ and SiNₓ etching results differed substantially, depending on whether HF was used alone or co-dosed with NH₃ or DMA. These systematic differences may be explained by the nature of the active etch species. Literature studies for aqueous HF solutions have established that SiO₂ wet etching is mainly determined by HF₂⁻ species. SiO₂ non-etch has also been reported for anhydrous, un-ionized HF. Likewise, studies for aqueous HF solutions have established that SiNₓ wet etching is largely determined by F species. The same studies have reported that un-ionized HF can etch SiNₓ at a lower reaction rate and HF₂⁻ species cannot etch SiNₓ. These results from wet solution etching can provide guidance to understand the active etch species present during gas-phase HF exposures and HF+NH₃ or DMA+HF co-dosing exposures.

During HF exposures at 3 Torr, HF may partially dissociate into H⁺ and F⁻ in the adsorbed HF layer on the surface. An adsorbed HF layer may be needed to solvate the H⁺ and F⁻ ions formed after HF dissociation. Other investigations have documented an adsorbed HF layer with hydrogen-bonding between the HF adsorbates on Al₂O₃ surfaces. HF dissociation in the adsorbed HF layer may not be extensive and most of the dissociation products may remain as F without continuing to form HF₂⁻. These conditions would favor SiNₓ etching based on the previous aqueous HF solution studies.

In contrast, during HF+NH₃ or DMA+HF co-dosing exposures at 3 Torr, HF dissociation may be more extensive. NH₃ or DMA may help to stabilize the H⁺ dissociation product and lead to higher concentrations of the F dissociation product. At the increased F concentrations, reaction of F with HF may produce HF₂⁻ surface species. These conditions would favor SiO₂ etching based on previous aqueous HF solution studies.

Without being bound by theory, H₂O is believed to have a similar effect on HF. An adsorbed H₂O layer can solvate H⁺ and F⁻ ions formed after HF dissociation. The formation of HF₂⁻ species then promotes SiO₂ etching. Consequently, the presence of H₂O can decrease the selectivity of SiNₓ etching compared to SiO₂ etching by increasing the SiO₂ etch rate. The vapor-phase SiO₂ etching with HF+methanol or HF+ethanol co-dosing also suggests a similar role for alcohols. The alcohol has been believed to facilitate HF dissociation and promote the formation of HF₂⁻ species for SiO₂ etching.

Without being bound by theory, an alternative explanation, is that NH₃ as an amine can catalyze reactions with hydroxyl groups on SiO₂. Si—OH surface species have a very acidic hydrogen with an isoelectric point (IEP) at a pH level around two. Amine coupling to this acidic hydrogen makes the oxygen in Si—OH surface species a much stronger nucleophile. As a result, NH₃ or DMA might catalyze the reaction of HF with Si—OH surface species to produce gaseous H₂O and Si—F surface species. In contrast, and without being bound by theory, NH₃ or DMA are not expected to interact in the same way with Si—NH₂ surface species on the SiNₓ films.

The terms and expressions employed herein are used as terms of description and not of limitation, and there is no intention in the use of such terms and expressions of excluding any equivalents of the features shown and described or portions thereof, but it is recognized that various modifications are possible within the scope of the embodiments of the present application. Thus, it should be understood that although the present application describes specific embodiments and optional features, modification and variation of the compositions, methods, and concepts herein disclosed may be resorted to by those of ordinary skill in the art, and that such modifications and variations are considered to be within the scope of embodiments of the present application.

### Enumerated Embodiments

The following enumerated embodiments are provided, the numbering of which is not to be construed as designating levels of importance:

Embodiment 1 provides a method of etching a substrate, the method comprising:
contacting, in a reaction chamber, the substrate with an etching reagent comprising hydrogen fluoride (HF) and optionally a polar molecule having a dipole moment of at least 1 Debye; and
etching the substrate,
wherein the substrate comprises silicon dioxide (SiO₂) and silicon nitride (SiNₓ).

Embodiment 2 provides the method of embodiment 1, wherein the etching reagent comprises HF and the silicon nitride is etched by F⁻ and the silicon dioxide is not substantially etched by F⁻.

Embodiment 3 provides the method of any one of embodiments 1-2, further comprising introducing the polar molecule having a dipole moment of at least 1 Debye into the reaction chamber.

Embodiment 4 provides the method of any one of embodiments 1-3, wherein the etching reagent comprises HF and the polar molecule, and wherein the silicon nitride is not substantially etched by HF₂⁻ and the silicon dioxide is etched by HF₂⁻.

Embodiment 5 provides the method of any one of embodiments 1-4, further comprising removing the polar molecule from the reaction chamber.

Embodiment 6 provides the method of any one of embodiments 1-5, comprising:
i) introducing the polar molecule having a dipole moment of at least 1 Debye into the reaction chamber, etching for a period, and removing the polar molecule having a dipole moment of at least 1 Debye from the reaction chamber after the period; or
ii) removing the polar molecule having a dipole moment of at least 1 Debye from the reaction chamber, etching for a period, and introducing the polar molecule having a dipole moment of at least 1 Debye into the reaction chamber after the period.

Embodiment 7 provides the method of any one of embodiments 1-6, wherein step i) and/or step ii) are each repeated at least twice.

Embodiment 8 provides the method of any one of embodiments 1-7, wherein the polar molecule is a polar aprotic molecule.

Embodiment 9 provides the method of any one of embodiments 1-8, wherein the polar aprotic molecule is selected from the group consisting of diethyl ether, dichloromethane, tetrahydrofuran, ethyl acetate, acetone, dimethylformamide, acetonitrile, dimethyl sulfoxide, and propylene carbonate.

Embodiment 10 provides the method of any one of embodiments 1-9, wherein the polar molecule is a polar protic molecule.

Embodiment 11 provides the method of any one of embodiments 1-10, wherein the polar protic molecule is selected from the group consisting of ammonia, methyl amine, dimethyl amine, ethylamine, pyridine, aniline, ethylenediamine, t-butanol, n-propanol, ethanol, methanol, acetic acid, ethylene glycol, and water.

Embodiment 12 provides the method of any one of embodiments 1-11, wherein the substrate further comprises at least one material selected from the group consisting of Si, SiNₓO_{y}, SiₓGe_{y}, SiC, SiB₃, SiP, SiAs, SiSe, SiTe, RuSi, TiₓSi_{y}, TiC_{z}, TiC, VₓSi_{y}, NbₓSi_{y}, MoₓSi_{y}, TaₓSi_{y}, ReₓSi_{y}, and WₓSi_{y},
wherein:
   each occurrence of x is independently an integer from 1 to 6;
   each occurrence of y is independently an integer from 1 to 6; and
   z is from about 0.3 to about 1.

Embodiment 13 provides the method of any one of embodiments 1-12, wherein the substrate further comprises a metal compound layer in which the metal is selected from the group consisting of Al, Hf, Zr, Fe, Ni, Co, Mn, Mg, Rh, Ru, Cr, Si, Ti, Sc, Ga, In, Zn, Pb, Ge, Ta, Cu, W, Mo, Pt, Nb, Cd and Sn, and combinations thereof.

Embodiment 14 provides the method of any one of embodiments 1-13, wherein the metal compound is selected from the group consisting of a metal oxide, metal nitride, metal phosphide, metal sulfide, metal arsenide, metal fluoride, metal silicide, metal boride, metal carbide, metal selenide, metal telluride, elemental metal, metal alloy, and hybrid organic-inorganic material.

Embodiment 15 provides the method of any one of embodiments 1-14, wherein the metal compound is a metal oxide.

Embodiment 16 provides the method of any one of embodiments 1-15, wherein the metal in the metal compound layer is Al.

Embodiment 17 provides the method of any one of embodiments 1-16, wherein the metal compound layer comprises Al₂O₃.

Embodiment 18 provides the method of any one of embodiments 1-17, wherein the metal compound layer is about 1 to about 100 Å thick.

Embodiment 19 provides the method of any one of embodiments 1-18, wherein the HF is provided in a dose of about 0.05 to about 200 Torr s.

Embodiment 20 provides the method of any one of embodiments 1-19, wherein the etching is performed at a temperature of about 150 to about 350° C.

Embodiment 21 provides the method of any one of embodiments 1-20, wherein the etching reagent comprises hydrogen fluoride (HF) and a polar molecule having a dipole moment of at least 1 Debye.

Embodiment 22 provides the method of any one of embodiments 1-21, wherein the polar molecule contains at least one lone pair of electrons.

Embodiment 23 provides the method of any one of embodiments 1-22, wherein the polar molecule is provided in a dose of about 0.05 to about 200 Torr s.

Embodiment 24 provides the method of any one of embodiments 1-23, wherein the polar molecule is ammonia (NH₃) or dimethyl amine (DMA).

Embodiment 25 provides the method of any one of embodiments 1-24, wherein the etching is spontaneous etching.

Embodiment 26 provides the method of any one of embodiments 1-25, wherein the etching is thermal atomic layer etching (ALE).

Embodiment 27 provides the method of any one of embodiments 1-26, wherein the etching reagent further comprises an alkyl aluminum species.

Embodiment 28 provides the method of any one of embodiments 1-27, wherein the alkyl aluminum species is Al(CH₃)₃.

What is claimed is:

1. A method of etching a substrate, the method comprising:
contacting, in a reaction chamber, the substrate with an etching reagent comprising hydrogen fluoride (HF) and optionally a polar molecule having a dipole moment of at least 1 Debye; and
etching the substrate,
wherein the substrate comprises silicon dioxide (SiO₂) and silicon nitride (SiNₓ).

2. The method of claim 1, wherein the etching reagent comprises HF and the silicon nitride is etched by F and the silicon dioxide is not substantially etched by F⁻.

3. The method of claim 1, further comprising introducing the polar molecule having a dipole moment of at least 1 Debye into the reaction chamber.

4. The method of claim 3, wherein the etching reagent comprises HF and the polar molecule, and wherein the silicon nitride is not substantially etched by HF₂⁻ and the silicon dioxide is etched by HF₂⁻.

5. The method of claim 3, further comprising removing the polar molecule from the reaction chamber.

6. The method of claim 1, comprising:
i) introducing the polar molecule having a dipole moment of at least 1 Debye into the reaction chamber, etching for a period, and removing the polar molecule having a dipole moment of at least 1 Debye from the reaction chamber after the period;
or
ii) removing the polar molecule having a dipole moment of at least 1 Debye from the reaction chamber, etching for a period, and introducing the polar molecule having a dipole moment of at least 1 Debye into the reaction chamber after the period.

7. The method of claim 6, wherein step i) and/or step ii) are each repeated at least twice.

8. The method of claim 1, wherein the polar molecule is a polar aprotic molecule.

9. The method of claim 8, wherein the polar aprotic molecule is selected from the group consisting of diethyl ether, dichloromethane, tetrahydrofuran, ethyl acetate, acetone, dimethylformamide, acetonitrile, dimethyl sulfoxide, and propylene carbonate.

10. The method of claim 1, wherein the polar molecule is a polar protic molecule.

11. The method of claim 10, wherein the polar protic molecule is selected from the group consisting of ammonia, methyl amine, dimethyl amine, ethylamine, pyridine, aniline, ethylenediamine, t-butanol, n-propanol, ethanol, methanol, acetic acid, ethylene glycol, and water.

12. The method of claim 1, wherein the substrate further comprises at least one material selected from the group consisting of Si, SiNₓO_{y}, SiₓGe_{y}, SiC, SiB₃, SiP, SiAs, SiSe, SiTe, RuSi, TiₓSi_{y}, TiC_{z}, TiC, VₓSi_{y}, NbₓSi_{y}, MoₓSi_{y}, TaₓSi_{y}, ReₓSi_{y}, and WₓSi_{y},
wherein:
each occurrence of x is independently an integer from 1 to 6;
each occurrence of y is independently an integer from 1 to 6; and
z is from about 0.3 to about 1.

13. The method of claim 1, wherein the substrate further comprises a metal compound layer in which the metal is selected from the group consisting of Al, Hf, Zr, Fe, Ni, Co, Mn, Mg, Rh, Ru, Cr, Si, Ti, Sc, Ga, In, Zn, Pb, Ge, Ta, Cu, W, Mo, Pt, Nb, Cd and Sn, and combinations thereof.

14. The method of claim 13, wherein the metal compound is selected from the group consisting of a metal oxide, metal nitride, metal phosphide, metal sulfide, metal arsenide, metal fluoride, metal silicide, metal boride, metal carbide, metal selenide, metal telluride, elemental metal, metal alloy, and hybrid organic-inorganic material.

15. The method of claim 14, wherein the metal compound is a metal oxide.

16. The method of claim 14, wherein the metal in the metal compound layer is Al.

17. The method of claim 14, wherein the metal compound layer comprises Al₂O₃.

18. The method of claim 14, wherein the metal compound layer is about 1 to about 100 Å thick.

19. The method of claim 1, wherein the HF is provided in a dose of about 0.05 to about 200 Torr s.

20. The method of claim 1, wherein the etching is performed at a temperature of about 150 to about 350° C.

21. The method of claim 1, wherein the etching reagent comprises hydrogen fluoride (HF) and a polar molecule having a dipole moment of at least 1 Debye.

22. The method of claim 1, wherein the polar molecule contains at least one lone pair of electrons.

23. The method of claim 1, wherein the polar molecule is provided in a dose of about 0.05 to about 200 Torr s.

24. The method of claim 1, wherein the polar molecule is ammonia (NH₃) or dimethyl amine (DMA).

25. The method of claim 1, wherein the etching is spontaneous etching.

26. The method of claim 1, wherein the etching is thermal atomic layer etching (ALE).

27. The method of claim 1, wherein the etching reagent further comprises an alkyl aluminum species.

28. The method of claim 27, wherein the alkyl aluminum species is Al(CH₃)₃.
